(19) United States
(12) Patent Application Publication
(10) Pub. No.: US 2024/0405757 A1
(43) Pub. Date: Dec. 5, 2024

(54) SWITCHING CIRCUIT

(71) Applicant: ROHM CO., LTD., Kyoto-shi (JP)

(72) Inventor: Seiji TAKENAKA, Kyoto-shi (JP)

(21) Appl. No.: 18/805,770

(22) Filed: Aug. 15, 2024

Related U.S. Application Data
(63) Continuation of application No. PCT/JP2023/004537, filed on Feb. 10, 2023.

(30) Foreign Application Priority Data
Feb. 24, 2022 (JP) 2022-026355

(51) Int. Cl. H03K 3/037; H03K 17/567

(52) U.S. Cl. CPC H03K 3/037; H03K 17/567

(57) ABSTRACT

A switching circuit includes: an output inverter that switches an output signal between high-level and low-level voltages; a first inverter that generates the high-level voltage from a first supply voltage according to a first input signal; a second inverter that generates the low-level voltage from a second supply voltage according to a second input signal; a first bias portion that lowers the voltage fed to the high-side power terminal of the first inverter by a first bias voltage to feed the result to the low-side power terminal of the first inverter; and a second bias portion that raises the voltage fed to a low-side power terminal of the second inverter by a second bias voltage to feed the result to the high-side power terminal of the second inverter.

### CROSS-REFERENCE TO RELATED APPLICATIONS

This application is a continuation under 35 U.S.C. § 120 of PCT/JP2023/004537 filed on Feb. 10, 2023, which is incorporated herein by reference, and which claimed priority to Japanese Patent Application No. 2022-026355 filed on Feb. 24, 2022. The present application likewise claims priority under 35 U.S.C. § 119 to Japanese Application No. 2022-026355, filed Feb. 24, 2022, the entire content of which is also incorporated herein by reference.

### TECHNICAL FIELD

The disclosure herein relates to a switching circuit.

### BACKGROUND ART

Conventionally, switching circuits (such as CMOS [complementary MOS] inverters) that switch their output signal between a high level and a low level based on their input signal are used in various applications.

An example of known technology related to what has just been mentioned is seen in Patent Document 1 identified below.

### CITATION LIST

### Patent Literature

Patent Document 1:JP-A-2009-277821

### BRIEF DESCRIPTION OF DRAWINGS

FIG. 1 is a diagram showing a comparative example of a switching circuit.

FIG. 2 is a diagram showing a switching circuit according to a first embodiment.

FIG. 3 is a diagram showing the voltages at relevant points in the switching circuit of the first embodiment.

FIG. 4 is a diagram showing a switching circuit according to a second embodiment.

FIG. 5 is a diagram showing the voltages at relevant points in the switching circuit of the second embodiment.

### DESCRIPTION OF EMBODIMENTS

### Switching Circuit (Comparative Example)

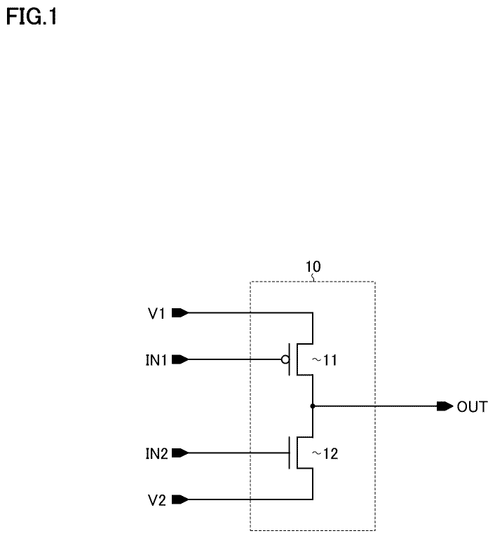

FIG. 1 is a diagram showing a comparative example (that is, a common configuration to be compared with the embodiments which will be described later) of a switching circuit. The switching circuit 10 of this comparative example includes, for example, a transistor 11 (for example, PMOSFET) and a transistor 12 (for example, NMOSFET).

The source of the transistor 11 is connected to an application terminal for a first supply voltage V1 (for example, 10.5 V). The source of the transistor 12 is connected to an application terminal for a second supply voltage V2 (for example,−3.5 V). The gate of the transistor 11 is connected to an input terminal for a first input signal IN1. The gate of the transistor 12 is connected to an input terminal for a second input signal IN2. The drains of the transistors 11 and 12 are both connected to an application terminal for an output signal OUT.

The gates of the transistors 11 and 12 may be short-circuited together. In that case, the switching circuit 10 functions as what is called a CMOS inverter.

First, consider a case where the first input signal IN1 is at low level (for example, IN1=V1−5 V) and the second input signal IN2 is at low level (for example, IN2=V2). In this case, the transistor 11 is on and the transistor 12 is off. Thus, the output signal OUT is at high level (OUT=V1).

Next, consider a case where the first input signal IN1 is at high level (for example, IN1=V1) and the second input signal IN2 is at high level (for example, IN=V2+5 V). In this case, the transistor 11 is off and the transistor 12 is on. Thus, the output signal OUT is at low level (OUT=V2).

As described above, in the switching circuit 10 of this comparative example, depending on the logic levels of the first and second input signals IN1 and IN2, the output signal OUT can be switched to either the first or second supply voltage V1 or V2.

However, in the switching circuit 10 of this comparative example, a high voltage V1-V2 (in terms of what is shown in the diagram, 14V at the maximum) is fed between the drain and the source of each of the transistors 11 and 12. Thus, it is necessary to use high-withstand-voltage elements for the transistors 11 and 12, and this requires additional layers (hence increased cost of the entire IC).

Out of the above considerations, a description will be given below of a novel embodiment that can reduce the withstand voltage of the internal elements of a switching circuit.

### Switching Circuit (First Embodiment)

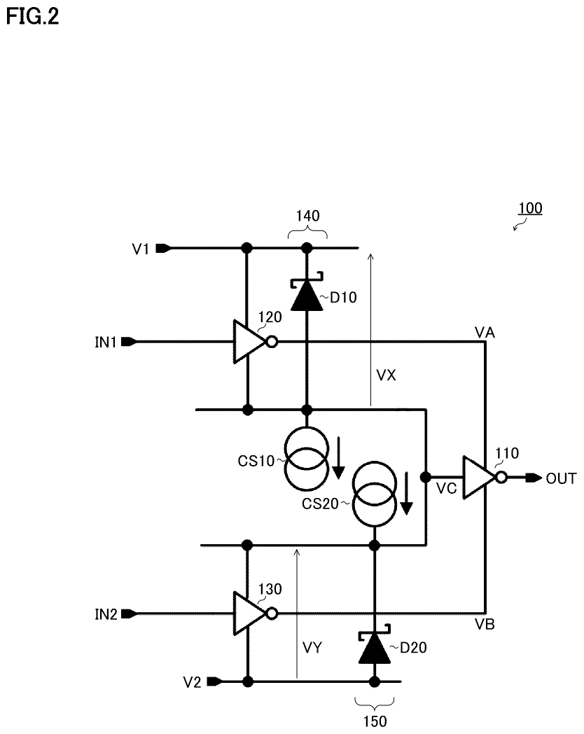

FIG. 2 is a diagram showing a switching circuit according to a first embodiment. The switching circuit 100 of this embodiment includes an output inverter 110, a first inverter 120, a second inverter 130, a first bias portion 140, and a second bias portion 150.

The high-side power terminal of the output inverter 110 is connected to an application terminal for a high-level voltage VA (that is, the output terminal of the first inverter 120). The low-side power terminal of the output inverter 110 is connected to an application terminal for a low-level voltage VB (that is, the output terminal of the second inverter 130). The input terminal of the output inverter 110 is connected to an application terminal for a node voltage VC (that is, the low-side power terminal of the first inverter 120 and the high-side power terminal of the second inverter 130). The output terminal of the output inverter 110 is connected to an application terminal for an output signal OUT.

So connected, the output inverter 110 switches the output signal OUT to either the high-level or low-level voltage VA or VB depending on the logic levels of the first and second input signals IN1 and IN2.

The high-side power terminal of the first inverter 120 is connected to an application terminal for the first supply voltage V1. The low-side power terminal of the first inverter 120 is connected to an application terminal for the node voltage VC. The input terminal of the first inverter 120 is connected to an application terminal for the first input signal IN1. The output terminal of the first inverter 120 is connected to an application terminal for the high-level voltage VA (that is, the high-side power terminal of the output inverter 110).

So connected, the first inverter 120 generates the high-level voltage VA from the first supply voltage V1 according to the first input signal IN1. In terms of what is shown in the diagram, the first inverter 120 outputs the high-level voltage VA that is pulse-driven between the first supply voltage V1 and the node voltage VC set by the first bias portion 140 (and the second bias portion 150).

The low-side power terminal of the second inverter 130 is connected to an application terminal for the second supply voltage V2. The high-side power terminal of the second inverter 130 is connected to the application terminal for the node voltage VC. The input terminal of the second inverter 130 is connected to an application terminal for the second input signal IN2. The output terminal of the second inverter 130 is connected to an application terminal for the low-level voltage VB (that is, the low-side power terminal of the output inverter 110).

So connected, the second inverter 130 generates the low-level voltage VB from the second supply voltage V2 according to the second input signal IN2. In terms of what is shown in the diagram, the second inverter 130 outputs the low-level voltage VB that is pulse-driven between the second supply voltage V2 and the node voltage VC set by the second bias portion 150 (and the first bias portion 140).

The output inverter 110, the first inverter 120, and the second inverter 130 described above may all be CMOS inverters.

The first bias portion 140 lowers, by a first bias voltage VX (for example, VX=(V1−V2)/2), the first supply voltage V1 fed to the high-side power terminal of the first inverter 120 and feeds the result to the low-side power terminal of the first inverter 120. In terms of what is shown in the diagram, the first bias portion 140 includes a diode D10 and a current source CS10.

The cathode of the diode D10 is connected to the application terminal for the first supply voltage V1 (that is, the high-side power terminal of the first inverter 120). The anode of the diode D10 is connected to the application terminal for the node voltage VC (that is, the low-side power terminal of the first inverter 120).

So connected, the terminal-to-terminal voltage (that is, breakdown voltage) across the diode D10 corresponds to the first bias voltage VH. The first bias voltage VX may be set to a voltage value lower than the withstand voltage of the internal elements (for example, the PMOSFET and NMOSFET that constitute the CMOS inverter) of each of the output inverter 110 and the first inverter 120.

Instead of the diode D10, a diode-connected transistor (that is, a transistor with its gate and drain short-circuited together) may be used. It is also possible to connect diodes D10 in multiple stages to obtain a desired first bias voltage VX.

The current source CS10 is connected to the application terminal for the node voltage VC and feeds a bias current to the diode D10.

The second bias portion 150 raises, by a second bias voltage VY (for example, VY=(V1−V2)/2), the second supply voltage V2 fed to the low-side power terminal of the second inverter 130, and feeds the result to the high-side power terminal of the second inverter 130. In terms of what is shown in the diagram, the second bias portion 150 includes a diode D20 and a current source CS20.

The anode of the diode D20 is connected to the application terminal for the second supply voltage V2 (that is, the low-side power terminal of the second inverter 130). The cathode of the diode D20 is connected to the application terminal for the node voltage VC (that is, the high-side power terminal of the second inverter 130).

So connected, the terminal-to-terminal voltage (that is, breakdown voltage) across the diode D20 corresponds to the second bias voltage VY. The second bias voltage VY can be set to a voltage value lower than the withstand voltage of the internal elements of the output inverter 110 and the second inverter 130 (for example, the PMOSFET and NMOSFET that constitute the CMOS inverter).

Instead of the diode D20, a diode-connected transistor (that is, a transistor with its gate and drain short-circuited together) may be used. It is also possible to connect diodes D20 in multiple stages to obtain a desired second bias voltage VY.

The current source CS20 is connected to the application terminal for the node voltage VC and feeds a bias current to the diode D20.

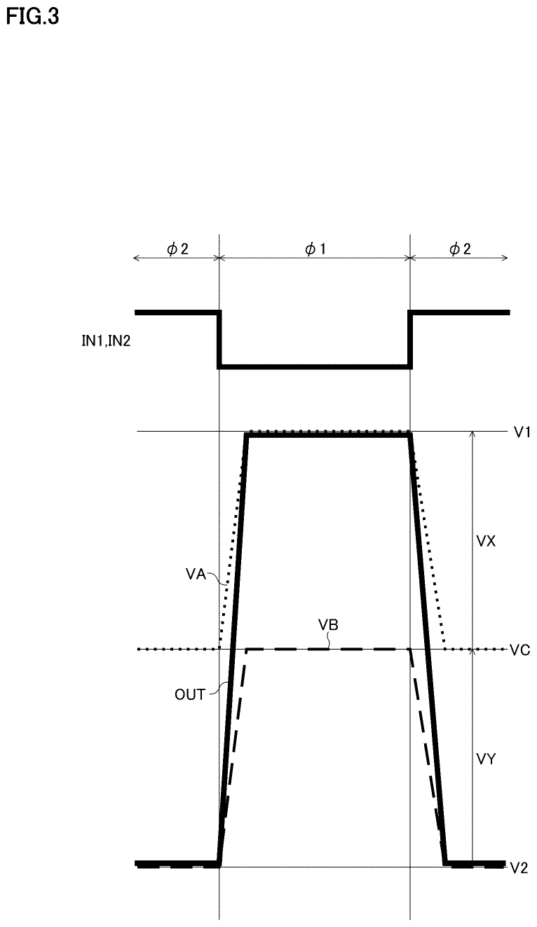

FIG. 3 is a diagram showing the voltages at relevant points in the switching circuit 100 of the first embodiment. In an upper part of FIG. 3, the first and second input signals IN1 and IN2 are depicted with a thick solid line and, in a lower part of FIG. 3, the output signal OUT is depicted with a thick solid line. In the lower part of the diagram, also the high-level voltage VA (a short-stroke broken line) and the low-level voltage VB (a long-stroke broken line) are depicted.

First, consider a first phase φ1 where the first input signal IN1 is at low level (for example, IN1=V1−5 V) and the second input signal IN2 is at low level (for example, IN2=V2). In this phase, the first inverter 120 logically inverts the low-level first input signal IN1 and outputs a high-level signal (that is, the first supply voltage V1). Thus, the high-level voltage VA fed to the high-side power terminal of the output inverter 110 equals the first supply voltage V1. The second inverter 130 logically inverts the low-level second input signal IN2 and outputs a high-level signal (that is, the node voltage VC). Thus, the low-level voltage VB fed to the low-side power terminal of the output inverter 110 equals the node voltage VC. As described above, the input terminal of the output inverter 110 is fed with the node voltage VC. As a result, the output signal OUT output from the output inverter 110 is the high-level voltage VA (=V1).

Next, consider a second phase φ2 where the first input signal IN1 is at high level (for example, IN1=V1) and the second input signal IN2 is at high level (for example, IN2=V2+5 V). In this phase, the first inverter 120 logically inverts the high-level first input signal IN1 and outputs a low-level signal (that is, the node voltage VC). Thus, the high-level voltage VA fed to the high-side power terminal of the output inverter 110 equals the node voltage VC. The second inverter 130 logically inverts the high-level second input signal IN2 and outputs a low-level signal (that is, the second supply voltage V2). Thus, the low-level voltage VB fed to the low-side power terminal of the output inverter 110 equals the second supply voltage V2. As described above, the input terminal of the output inverter 110 is fed with the node voltage VC. As a result, the output signal OUT output from the output inverter 110 is the low-level voltage VB (=V2).

As described above, with the switching circuit 100 of this embodiment, the output signal OUT can be switched to either the high-level voltage VA (=V1 in φ1) or the low-level voltage VB (=V2 in φ2) depending on the logic levels of the first and second input signals IN1 and IN2.

Incidentally, with focus on the first phase φ1, between the high-side power terminal (VA=V1) and the low-side power terminal (VB=VC) of the output inverter 110, only the first bias voltage VX (=V1−VC) is applied. On the other hand, with focus on the second phase φ2, between the high-side power terminal (VA=VC) and the low-side power terminal (VB=V2) of the output inverter 110, only the second bias voltage VY (=VC−V2) is applied. In both the first and second phases φ1 and φ2, only the first bias voltage VX is applied to the first inverter 120, and only the second bias voltage VY is applied to the second inverter 130.

In this way, with the switching circuit 100 of this embodiment, the high voltage V1-V2 is fed to none of the output inverter 110, the first inverter 120, and the second inverter 130. Thus, it is possible to reduce the withstand voltage of the internal elements (for example, the PMOSFET and NMOSFET constituting the CMOS inverter) of the output inverter 110, the first inverter 120, and the second inverter 130. As a result, it is possible to reduce the layers (hence reduce the cost of the entire IC).

### Switching Circuit (Second Embodiment)

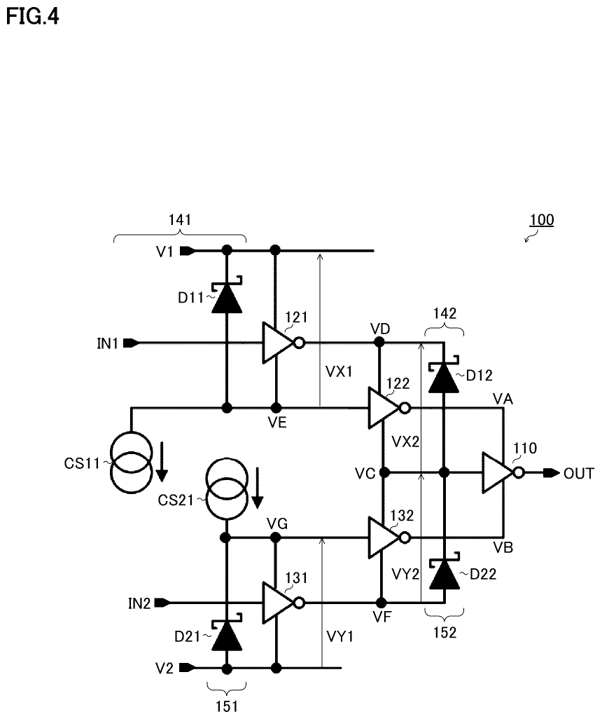

FIG. 4 is a diagram showing a switching circuit according to a second embodiment. The switching circuit 100 of this embodiment, while being based on the first embodiment (FIG. 2) described previously, includes multiple stages of each of the previously-described first inverter 120, second inverter 130, first bias portion 140, and second bias portion 150 (in FIG. 4, two each of them, one in an initial stage (first stage) and another in a final stage (second stage)).

In terms of what is shown in the diagram, the switching circuit 100 of this embodiment includes the output inverter 110 described previously, first inverters 121 and 122, second inverters 131 and 132, first bias portions 141 and 142, and second bias portions 151 and 152.

The high-side power terminal of the output inverter 110 is connected to the application terminal for the high-level voltage VA (that is, the output terminal of the first inverter 122). The low-side power terminal of the output inverter 110 is connected to the application terminal for the low-level voltage VB (that is, the output terminal of the second inverter 132). The input terminal of the output inverter 110 is connected to the application terminal for the node voltage VC (that is, the low-side power terminal of the first inverter 122 and the high-side power terminal of the second inverter 132). The output terminal of the output inverter 110 is connected to the application terminal for the output signal OUT.

So connected, the output inverter 110 switches the output signal OUT to either the high-level or low-level voltage VA or VB depending on the logic levels of the first and second input signals IN1 and IN2.

The high-side power terminal of the first inverter 121 is connected to the application terminal for the first supply voltage V1. The low-side power terminal of the first inverter 121 is connected to an application terminal for a node voltage VE (that is, the input terminal of the first inverter 122). The input terminal of the first inverter 121 is connected to the application terminal for the first input signal IN1. The output terminal of the first inverter 121 is connected to an application terminal for a node voltage VD (that is, the high-side power terminal of the first inverter 122).

The high-side power terminal of the first inverter 122 is connected to the application terminal for the node voltage VD. The low-side power terminal of the first inverter 122 is connected to the application terminal for the node voltage VC (that is, the input terminal of the output inverter 110). The input terminal of the first inverter 122 is connected to the application terminal for the node voltage VE (that is, the low-side power terminal of the first inverter 121). The output terminal of the first inverter 122 is connected to the application terminal for the high-level voltage VA (that is, the high-side power terminal of the output inverter 110).

So connected, the first inverters 121 and 122 generate the high-level voltage VA from the first supply voltage V1 according to the first input signal IN1. In terms of what is shown in the diagram, the first inverter 121 outputs the node voltage VD that is pulse-driven between the first supply voltage V1 and the node voltage VE (=V1−VX1) set by the first bias portion 141. The first inverter 122 outputs the high-level voltage VA that is pulse-driven between the node voltage VD and the node voltage VC set by the first bias portion 142 (and the second bias portion 152).

The low-side power terminal of the second inverter 131 is connected to the application terminal for the second supply voltage V2. The high-side power terminal of the second inverter 131 is connected to an application terminal for a node voltage VG (that is, the input terminal of the second inverter 132). The input terminal of the second inverter 131 is connected to the application terminal for the second input signal IN2. The output terminal of the second inverter 131 is connected to the application terminal for a node voltage VF (that is, the low-side power terminal of the second inverter 132).

The low-side power terminal of the second inverter 132 is connected to the application terminal for the node voltage VF. The high-side power terminal of the second inverter 132 is connected to the application terminal for the node voltage VC (that is, the input terminal of the output inverter 110). The input terminal of the second inverter 132 is connected to the application terminal for the node voltage VG (that is, the high-side power terminal of the second inverter 131). The output terminal of the second inverter 132 is connected to the application terminal for the low-level voltage VB (that is, the low-side power terminal of the output inverter 110).

So connected, the second inverters 131 and 132 generate the low-level voltage VB from the second supply voltage V2 according to the second input signal IN2. In terms of what is shown in the diagram, the second inverter 131 outputs the node voltage VF that is pulse-driven between the second supply voltage V2 and the node voltage VG (=V2+VY1) set by the second bias portion 151. The second inverter 132 also outputs the low-level voltage VB that is pulse-driven between the node voltage VF and the node voltage VC set by the second bias portion 152 (and the first bias portion 142).

The output inverter 110, the first inverters 121 and 122, and the second inverters 131 and 132 described above may all be CMOS inverters.

The first bias portion 141 lowers, by a first bias voltage VX1 (for example, VX1=(V1−V2)/4), the first supply voltage V1 fed to the high-side power terminal of the first inverter 121 and feeds the result to the low-side power terminal of the first inverter 121. In terms of what is shown in the diagram, the first bias portion 141 includes a diode D11 and a current source CS11.

The cathode of the diode D11 is connected to the application terminal for the first supply voltage V1 (that is, the high-side power terminal of the first inverter 121). The anode of the diode D11 is connected to the application terminal for the node voltage VE (that is, the low-side power terminal of the first inverter 121).

So connected, the terminal-to-terminal voltage (that is, breakdown voltage) across the diode D11 corresponds to the first bias voltage VX1. The first bias voltage VX1 may be set to a voltage value lower than the withstand voltage of the internal elements (for example, the PMOSFET and NMOSFET that constitute the CMOS inverter) of the first inverter 121.

Instead of the diode D11, a diode-connected transistor (that is, a transistor with its gate and drain short-circuited together) may be used. It is also possible to connect diodes D11 in multiple stages to obtain the desired first bias voltage VX1.

The current source CS11 is connected to the application terminal for the node voltage VE and feeds a bias current to the diode D11.

The first bias portion 142 lowers, by a first bias voltage VX2 (for example, VX2=(V1−V2)/4), the node voltage VD fed to the high-side power terminal of the first inverter 122 and feeds the result to the low-side power terminal of the first inverter 122. In terms of what is shown in the diagram, the first bias portion 142 includes a diode D12.

The cathode of the diode D12 is connected to the application terminal for the node voltage VD (that is, the high-side power terminal of the first inverter 122). The anode of the diode D12 is connected to the application terminal for the node voltage VC (that is, the low-side power terminal of the first inverter 122).

So connected, the terminal-to-terminal voltage (that is, breakdown voltage) across the diode D12 corresponds to the first bias voltage VX2. The first bias voltage VX2 may be set to a voltage value lower than the withstand voltage of the internal elements (for example, the PMOSFET and NMOSFET that constitute the CMOS inverter) of the first inverter 122.

Instead of the diode D12, a diode-connected transistor (that is, a transistor with its gate and drain short-circuited together) may be used. It is also possible to connect diodes D12 in multiple stages to obtain the desired first bias voltage VX2.

The second bias portion 151 raises, by a second bias voltage VY1 (for example, VY=(V1−V2)/4), the second supply voltage V2 fed to the low-side power terminal of the second inverter 131, and feeds the result to the high-side power terminal of the second inverter 131. In terms of what is shown in the diagram, the second bias portion 151 includes a diode D21 and a current source CS21.

The anode of the diode D21 is connected to the application terminal for the second supply voltage V2 (that is, the low-side power terminal of the second inverter 131). The cathode of the diode D21 is connected to the application terminal for the node voltage VG (that is, the high-side power terminal of the second inverter 131).

So connected, the terminal-to-terminal voltage (that is, breakdown voltage) across the diode D21 corresponds to the second bias voltage VY1. The second bias voltage VY1 may be set to a voltage value lower than the withstand voltage of the internal elements (for example, the PMOSFET and NMOSFET that constitute the CMOS inverter) of the second inverter 131.

Instead of the diode D21, a diode-connected transistor (that is, a transistor with its gate and drain short-circuited together) may be used. It is also possible to connect diodes D21 in multiple stages to obtain a desired second bias voltage VY1.

The current source CS21 is connected to the application terminal for the node voltage VG and feeds a bias current to the diode D21.

The second bias portion 152 raises, by a second bias voltage VY2 (for example, VY2=(V1−V2)/4), the node voltage VF fed to the low-side power terminal of the second inverter 132, and feeds the result to the high-side power terminal of the second inverter 132. In terms of what is shown in the diagram, the second bias portion 152 includes a diode D22.

The anode of the diode D22 is connected to the application terminal for the node voltage VF (that is, the low-side power terminal of the second inverter 132). The cathode of the diode D22 is connected to the application terminal for the node voltage VC (that is, the high-side power terminal of the second inverter 132).

So connected, the terminal-to-terminal voltage (that is, breakdown voltage) across the diode D22 corresponds to the second bias voltage VY2. The second bias voltage VY2 may be set to a voltage value lower than the withstand voltage of the internal elements (for example, the PMOSFET and NMOSFET that constitute the CMOS inverter) of the second inverter 132.

Instead of the diode D22, a diode-connected transistor (that is, a transistor with its gate and drain short-circuited together) may be used. It is also possible to connect diodes D22 in multiple stages to obtain a desired second bias voltage VY2.

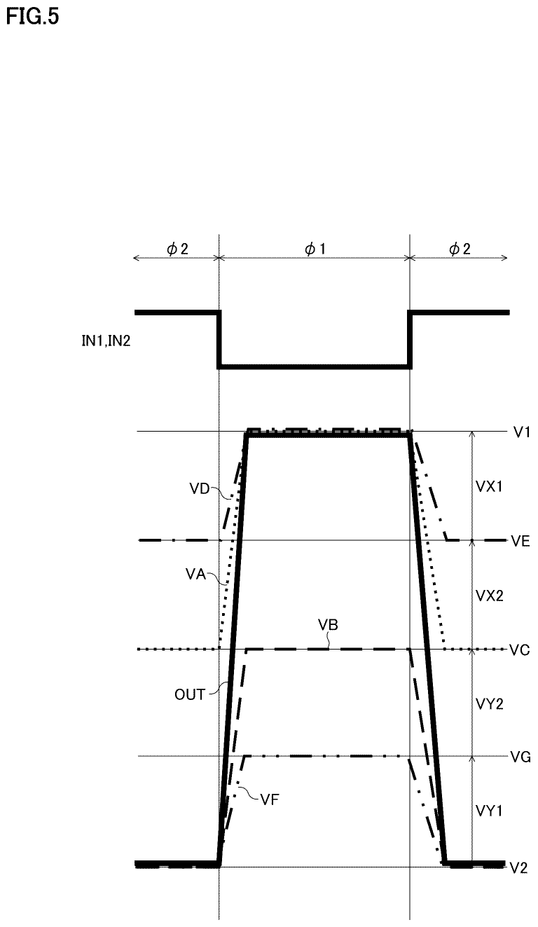

FIG. 5 is a diagram showing the voltages at relevant points in the switching circuit 100 of the second embodiment. In an upper part of FIG. 5, the first and second input signals IN1 and IN2 are depicted with a thick solid line and, in a lower part of FIG. 5, the output signal OUT is depicted with a thick solid line. In the lower part of the diagram, in addition to the high-level voltage VA (a short-stroke broken line) and the low-level voltage VB (a long-stroke broken line), also the node voltages VD (a dash-dot line) and VF (a dash-dot-dot line) are depicted.

First, consider a first phase φ1 where the first input signal IN1 is at low level (for example, IN1=V1−5 V) and the second input signal IN2 is at low level (for example, IN2=V2).

In this phase, the first inverter 121 logically inverts the low-level first input signal IN1 and outputs a high-level signal (that is, the first supply voltage V1). Thus, the node voltage VD fed to the high-side power terminal of the first inverter 122 equals the first supply voltage V1. On the other hand, the input terminal of the first inverter 122 is fed with the node voltage VE (=V1−VX1) that is lower than the first supply voltage V1. As a result, the first inverter 122 is in a high level output state, and thus the high-level voltage VA fed to the high-side power terminal of the output inverter 110 equals the node voltage VD (and hence the first supply voltage V1).

The second inverter 131 logically inverts the low-level second input signal IN2 and outputs a high-level signal (that is, the node voltage VG). Thus, the node voltage VF fed to the low-side power terminal of the second inverter 132 equals the node voltage VG fed to the input terminal of the second inverter 132. Here, the second inverter 132 is in a high level output state, and thus the low-level voltage VB fed to the low-side power terminal of the output inverter 110 equals the node voltage VC. As described above, the input terminal of the output inverter 110 is fed with the node voltage VC. As a result, the output signal OUT output from the output inverter 110 is the high-level voltage VA (=VD=V1).

Next, consider a second phase φ2 where the first input signal IN1 is at high level (for example, IN1=V1) and the second input signal IN2 is at high level (for example, IN2=V2+5 V).

In this phase, the second inverter 131 logically inverts the high-level second input signal IN2 and outputs a low-level signal (that is, the second supply voltage V2). Thus, the node voltage VF fed to the low-side power terminal of the second inverter 132 equals the second supply voltage V2. On the other hand, the input terminal of the second inverter 132 is fed with the node voltage VG (=V2+VY1) that is higher than the second supply voltage V2. As a result, the second inverter 132 is in a low level output state, and thus the low-level voltage VB fed to the low-side power terminal of the output inverter 110 equals the node voltage VF (and hence the second supply voltage V2).

The first inverter 121 logically inverts the high-level first input signal IN1 and outputs a low-level signal (that is, the node voltage VE). Thus, the node voltage VD fed to the high-side power terminal of the first inverter 122 equals the node voltage VE fed to the input terminal of the first inverter 122. Here, the first inverter 122 is in a low level output state, and thus the high-level voltage VA fed to the high-side power terminal of the output inverter 110 equals the node voltage VC. As described above, the input terminal of the output inverter 110 is fed with the node voltage VC. As a result, the output signal OUT output from the output inverter 110 is the low-level voltage VB (=VF=V2).

As described above, with the switching circuit 100 of this embodiment, as with the first embodiment (FIG. 1) described previously, the output signal OUT can be switched to either the high-level voltage VA (=V1 in φ1) or the low-level voltage VB (=V2 in φ2) depending on the logic levels of the first and second input signals IN1 and IN2.

Incidentally, with focus on the first phase φ1, between the high-side power terminal (VA=V1) and the low-side power terminal (VB=VC) of the output inverter 110, only the sum of the first bias voltages VX1 and VX2 (=V1−VC) is applied. On the other hand, with focus on the second phase φ2, between the high-side power terminal (VA=VC) and the low-side power terminal (VB=V2) of the output inverter 110, only the sum of the second bias voltages VY1 and VY2 (=VC−V2) is applied. In either of the first and second phases φ1 and 2, to the first inverters 121 and 122, only the first bias voltages VX1 and VX2 are applied respectively, and to the second inverters 131 and 132, only the second bias voltages VY1 and VY2 are applied respectively.

In this way, with the switching circuit 100 of this embodiment, the high voltage V1-V2 is fed to none of the output inverter 110, the first inverters 121 and 122, and the second inverters 131 and 132.

Thus, it is possible to reduce the withstand voltage of the internal elements (for example, the PMOSFET and NMOSFET constituting the CMOS inverter) of the output inverter 110, the first inverters 121 and 122, and the second inverters 131 and 132. As a result, it is possible to reduce the layers (hence reduce the cost of the entire IC).

In particular, with the switching circuit 100 of this embodiment, by connecting inverters in multiple stages, it is possible to reduce the voltage applied to (distribute it among) individual inverters. Thus, it is possible to lower the withstand voltage of the internal components even further compared to the first embodiment (FIG. 2) described previously.

### OVERVIEW

To follow is an overview of the various embodiments described above.

For example, according to one aspect of what is disclosed herein, a switching circuit includes: an output inverter configured to switch an output signal to either a high-level voltage or a low-level voltage; at least one stage of a first inverter configured to generate the high-level voltage from a first supply voltage according to a first input signal; at least one stage of a second inverter configured to generate the low-level voltage from a second supply voltage according to a second input signal; at least one stage of a first bias portion configured to lower the voltage fed to the high-side power terminal of the first inverter in each stage by a first bias voltage and to feed the lowered voltage to the low-side power terminal of the first inverter in each stage; and at least one stage of a second bias portion configured to raise the voltage fed to the low-side power terminal of the second inverter in each stage by a second bias voltage and to feed the raised voltage to the high-side power terminal of the second inverter in each stage. (A first configuration.)

In the switching circuit according to the first configuration described above, preferably, the first inverter in the first stage outputs a voltage that is pulse-driven between the first supply voltage and the voltage set by the first bias portion in the first stage. The first inverter in the second or any subsequent stage may output a voltage that is pulse-driven between the voltage output from the first inverter in the preceding stage and the voltage set by the first bias portion in the second or any subsequent stage. The voltage output from the first inverter in the final stage may be the high-level voltage. (A second configuration.)

In the switching circuit according to the first or second configuration described above, preferably, the second inverter in the first stage outputs a voltage that is pulse-driven between the second supply voltage and the voltage set by the second bias portion in the first stage. The second inverter in the second or any subsequent stage may output a voltage that is pulse-driven between the voltage output from the second inverter in the preceding stage and the voltage set by the second bias portion in the second or any subsequent stage. The voltage output from the second inverter in the final stage may be the low-level voltage. (A third configuration.)

In the switching circuit according to any of the first to third configurations described above, preferably, the input terminal of the first inverter in the first stage is connected to an application terminal for the first input signal. The input terminal of the first inverter in the second or any subsequent stage may be connected to the low-side power terminal of the first inverter in the preceding stage. (A fourth configuration.)

In the switching circuit according to any of the first to fourth configurations described above, preferably, the input terminal of the second inverter in the first stage is connected to an application terminal for the second input signal. The input terminal of the second inverter in the second or any subsequent stage may be connected to the high-side power terminal of the second inverter in the preceding stage. (A fifth configuration.)

In the switching circuit according to any of the first to fifth configurations described above, preferably, the input terminal of the output inverter is connected to the low-side power terminal of the first inverter in the final stage and to the high-side power terminal of the second inverter in the final stage. (A sixth configuration.)

In the switching circuit according to any of the first to sixth configurations described above, preferably, the output inverter and the first and second inverters in each stage are all CMOS inverters. (A seventh configuration.)

In the switching circuit according to the seventh configuration, preferably, the first and second bias voltages are lower than the withstand voltage of the transistors that constitute the CMOS inverter. (An eighth configuration.)

In the switching circuit according to the eighth configuration, preferably, the first and second bias portions each include a diode or a diode-connected transistor that is configured to generate the first and second bias voltages. (A ninth configuration.)

In the switching circuit according to the ninth configuration, preferably, each of the first and second bias portions further includes a current source configured to supply a bias current to the diode or the diode-connected transistor. (A tenth configuration.)

With the disclosure herein, it is possible to provide a switching circuit that can reduce the withstand voltage of its internal elements.

### FURTHER MODIFICATIONS

The various technical features disclosed herein may be implemented in any other manners than in the embodiments described above, and allow for any modifications made without departure from their technical ingenuity. That is, the embodiments described above should be considered to be illustrative in all respects and should not be considered to be restrictive. It should be understood that the technical scope of the present disclosure is defined by the scope of claims and encompasses any modifications made in a scope and sense equivalent to the scope of claims.

1. A switching circuit comprising:
an output inverter configured to switch an output signal to either a high-level voltage or a low-level voltage,
at least one stage of a first inverter configured to generate the high-level voltage from a first supply voltage according to a first input signal,
at least one stage of a second inverter configured to generate the low-level voltage from a second supply voltage according to a second input signal,
at least one stage of a first bias portion configured to lower a voltage fed to a high-side power terminal of the first inverter in each stage by a first bias voltage and to feed a lowered voltage to a low-side power terminal of the first inverter in each stage; and
at least one stage of a second bias portion configured to raise a voltage fed to a low-side power terminal of the second inverter in each stage by a second bias voltage and to feed a raised voltage to a high-side power terminal of the second inverter in each stage.

2. The switching circuit according to claim 1,
wherein
the first inverter in a first stage outputs a voltage that is pulse-driven between the first supply voltage and a voltage set by the first bias portion in the first stage,
the first inverter in a second or any subsequent stage outputs a voltage that is pulse-driven between a voltage output from the first inverter in a preceding stage and a voltage set by the first bias portion in the second or any subsequent stage, and
a voltage output from the first inverter in a final stage is the high-level voltage.

3. The switching circuit according to claim 1,
wherein
the second inverter in the first stage outputs a voltage that is pulse-driven between the second supply voltage and a voltage set by the second bias portion in the first stage,
the second inverter in a second or any subsequent stage outputs a voltage that is pulse-driven between a voltage output from the second inverter in a preceding stage and a voltage set by the second bias portion in the second or any subsequent stage, and
the voltage output from the second inverter in a final stage is the low-level voltage.

4. The switching circuit according to claim 1,
wherein
an input terminal of the first inverter in a first stage is connected to an application terminal for the first input signal, and
an input terminal of the first inverter in a second or any subsequent stage is connected to the low-side power terminal of the first inverter in a preceding stage.

5. The switching circuit according to claim 1,
wherein
an input terminal of the second inverter in a first stage is connected to an application terminal for the second input signal, and
an input terminal of the second inverter in a second or any subsequent stage is connected to the high-side power terminal of the second inverter in a preceding stage.

6. The switching circuit according to claim 1,
wherein
an input terminal of the output inverter is connected to the low-side power terminal of the first inverter in a final stage and to the high-side power terminal of the second inverter in the final stage.

7. The switching circuit according to claim 1,
wherein
the output inverter and the first and second inverters in each stage are all CMOS inverters.

8. The switching circuit according to claim 7,
wherein
the first and second bias voltages are lower than a withstand voltage of transistors that constitute the CMOS inverter.

9. The switching circuit according to claim 1,
wherein
the first and second bias portions each include a diode or a diode-connected transistor that is configured to generate the first and second bias voltages.

10. The switching circuit according to claim 9.
wherein
each of the first and second bias portions further includes a current source configured to supply a bias current to the diode or the diode-connected transistor.
